(19) United States
(12) Patent Application Publication
(10) Pub. No.: US 2019/0385958 A1
(43) Pub. Date: Dec. 19, 2019

(54) DISPLAY SUBSTRATE, DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventor: Guanghui HONG, Wuhan, Hubei (CN)

(21) Appl. No.: 15/735,931

(22) PCT Filed: Nov. 23, 2017
(86) PCT No.: PCT/CN2017/112451

§ 371 Date: Dec. 12, 2017

(30) Foreign Application Priority Data
Sep. 26, 2017 (CN) 201710887957.6

(51) Int. Cl. H01L 23/60

(52) U.S. Cl. CPC H01L 23/60; H01L 21/78

(57) ABSTRACT

The disclosure discloses a display substrate, a display panel, and a display device. The display substrate includes: a substrate defining multiple panel areas; signal lines arranged in each of the panel areas; wherein at least part of the signal lines between at least two of the panel areas are connected. In the disclosure, at least part of the signal lines connected between the at least two panel areas are added on the display substrate. Therefore, through the connected signal lines, the different panel areas or display substrates may be conducted, may cooperate with each other to resist the electrostatic damage, thereby effectively improving the occurrence of the damage at the electrostatic discharge monitoring points when the ESD of the process occurs and improving the yield of the product.

### RELATED APPLICATIONS

The present application is a National Phase of International Application Number PCT/CN2017/112451, filed Nov. 23, 2017, and claims the priority of China Application No. 201710887957.6, filed Sep. 26, 2017.

### FIELD OF THE DISCLOSURE

The disclosure relates to a display technical field, and more particularly to a display substrate, a display panel and a display device.

### BACKGROUND

With the gradual development of liquid crystal display (LCD) technology, the LCD panel has involved in all aspects of user's life, such as PC, smart phones and tablet PC.

The ESD of the process refers to the ESD generated due to a table or material during the production of glass panel, it is a big threat to the yield of the glass panel. In the current design solution, in order to ensure the normal function of the substrate, each substrate is usually independently distributed in the glass panel. However, this design solution is limited to the ESD of process not be effectively conducted. That is, when the ESD of the process occurs on any one position in the glass panel, the ESD may only be conducted in a limited space, thereby causing the substrate to be damaged by the ESD and affecting the yield of the process.

As shown in FIG. 1 and FIG. 2, FIG. 1 is a structural schematic view of a distribution of a substrate in the conventional glass panel process, and FIG. 2 is a structural schematic top view of the display substrate in FIG. 1 after cutting. As can be seen from FIGS. 1 and 2, the substrate is rationally distributed in the glass panel according to the design requirements, so as to maximize the utilization of the glass panel (maximized utilization of glass). The schematic diagram includes a schematic view of the substrate, a cut line position, and a glass edge. In addition, in the glass panel, a first metal layer M1 layer as Gate101 wiring may easily occur ESD damage, and AA area in the substrate has a large area of Gate101 wrings formed by the M1 layer. Therefore, in the existing design solution, once the ESD of the process occurs in one or several Gate101 wirings of one substrate, the ESD may only be conducted in the one or several Gate101 wirings of the substrate, it may easily occurs the ESD damage and the yield of the product process is affected.

At 100: it is a schematic view of the distribution of the substrate in the conventional glass panel process, in order to ensure the normal function of the substrate, each substrate is usually independently distributed in the glass panel. That is, there is no connected relationship therebetween.

At 200: it is assumed that the location of occurrence of the ESD of the process in the commonly used design solution. Since each substrate is independently distributed in the glass panel, once the ESD of the process occurs in one or several Gate101 wirings of the substrate, the ESD may only be conducted in the one or several Gate101 wirings of the substrate, it may easily occurs the ESD damage,

Therefore, a damage may easily be occurred at the electrostatic discharge monitoring points in the existing display substrate or the display panel, thereby affecting the yield of the product.

### SUMMARY

A technical problem to be solved by the disclosure is to provide a display substrate, a display panel and a display device, thereby effectively improving damages occurred at the electrostatic discharge monitoring points when the ESD of the process occurs and improving the yield of the product.

In order to solve the above technical problem, a first aspect of the disclosure is to provide a display substrate, including: a substrate defining a plurality of panel areas; and signal lines arranged in each of the panel areas; wherein at least part of the signal lines between at least two of the panel areas are connected.

In order to solve the above technical problem, a second aspect of the disclosure is to provide a display panel, including: a substrate; signal lines disposed on the substrate; wherein the signal lines extend to the edge of the substrate by itself or through wires for connecting to signal lines of another display substrate when the display panel is manufactured to cooperate with each other to resist electrostatic damages.

In order to solve the above technical problem, a third aspect of the disclosure is to provide a display device comprising: a substrate; signal lines disposed on the substrate; wherein the signal lines extend to the edge of the substrate by itself or through wires for connecting to signal lines of another display substrate when the display panel is manufactured to cooperate with each other to resist electrostatic damages.

Advantageous effects of the disclosure is that, different from the prior art, in the embodiment, at least part of the signal lines connected between the at least two panel areas are added on the display substrate, or the signal lines of the display substrate and another display substrate are connected. Therefore, through the connected signal lines, the different panel areas or display substrates may be conducted, may cooperate with each other to resist the electrostatic damage, thereby effectively improving the occurrence of the damages at the electrostatic discharge monitoring points when the ESD of the process occurs and improving the yield of the product.

### BRIEF DESCRIPTION OF THE DRAWINGS

FIG. 1 is a structural schematic top view of a display substrate in the prior art;

FIG. 2 is a structural schematic top view of the display substrate in FIG. 1 after cutting;

FIG. 3 is a structural schematic top view of a display substrate according to an embodiment of the disclosure;

FIG. 4 is a structural schematic top view of the display substrate in FIG. 3 after cutting;

FIG. 5 is a structural schematic cross-sectional view of the display substrate in FIG. 3 after cutting;

FIG. 6 is a structural schematic top view of a display substrate according to an embodiment of the disclosure; and

FIG. 7 is a structural schematic view of a display device according to an embodiment of the disclosure.

### DETAILED DESCRIPTION OF PREFERRED EMBODIMENTS

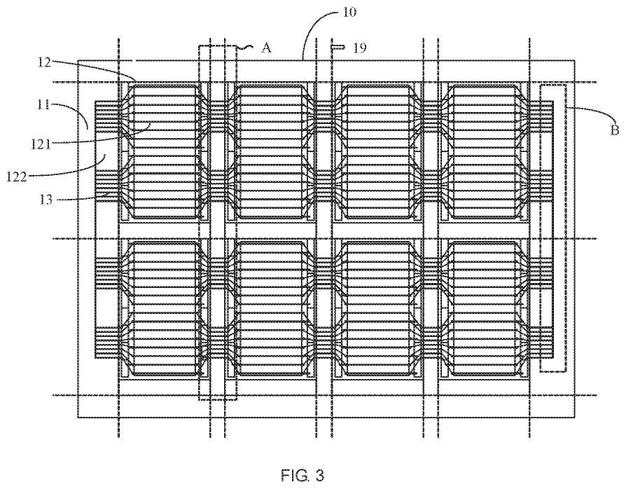

As shown in FIG. 3, FIG. 3 is a structural schematic top view of a display substrate according to an embodiment of the disclosure. In the embodiment, the display substrate 10 includes a substrate 11 and signal lines 13.

A plurality of panel areas 12 are defined in the substrate 11, and the panel areas 12 are disposed adjacent to each other. The signal lines 13 are arranged in each of the panel areas 12. When cutting, the signal line 13 may be cut off by the cutting line 19, and area A is a schematic range of the cutting area. Refer to A in FIG. 3, at least part of the signal lines 13 between at least two panel areas 12 are connected, Preferably, at least part of the signal lines 13 between the adjacent panel areas 12 are connected. Wherein the signal lines 13 may be gate lines.

Further refer to FIG. 5, FIG. 5 a structural schematic cross-sectional view of the display substrate in FIG. 3 after cutting. Specifically, the signal lines 13 are formed by using a first conductive layer 131, and the display substrate 10 includes a second conductive layer 133 disposed on and insulated from the first conductive layer 131. The first conductive layer 131, an insulating layer 132, and the second conductive layer 133 are sequentially arranged on a side surface of a glass layer 130. At least part of the signal lines 13 between at least two panel areas 12 are connected by the second conductive layer 133. That is, the first conductive layer 131 and the second conductive layer 133 have an indirect connection relationship. The panel areas 12 include a display area 121 and a non-display area 122 other than the display area 121, and connection points of the signal lines 13 and the second conductive layer 133 are located in the non-display area 122. Such connection is to prevent a display fault and ensure the display effect of the product. Preferably, the second conductive layer 133 is formed of an ITO layer or a M3 layer. The M3 layer is, for example, a pixel electrode layer.

Refer to B in the FIG. 5, a plurality of adjacent signal lines 13 of one panel area 12 are connected to connection lines formed by the second conductive layer 133 via holes in the non-display area 122. A plurality of connection lines corresponding to the plurality of adjacent signal lines 13 continue to convergently extend to the another panel area 12, so as to bypass the electrostatic discharge monitoring points and to connect to the corresponding signal lines 13 of another panel area 12. That is, most of the signal lines 13 are a fold line structure, and a small part of the signal lines 13 may be designed as a linear structure. For example, in the embodiment, the signal lines 13 located in the middle portion may be designed as the linear structure. In other embodiments, it may be set according to actual needs.

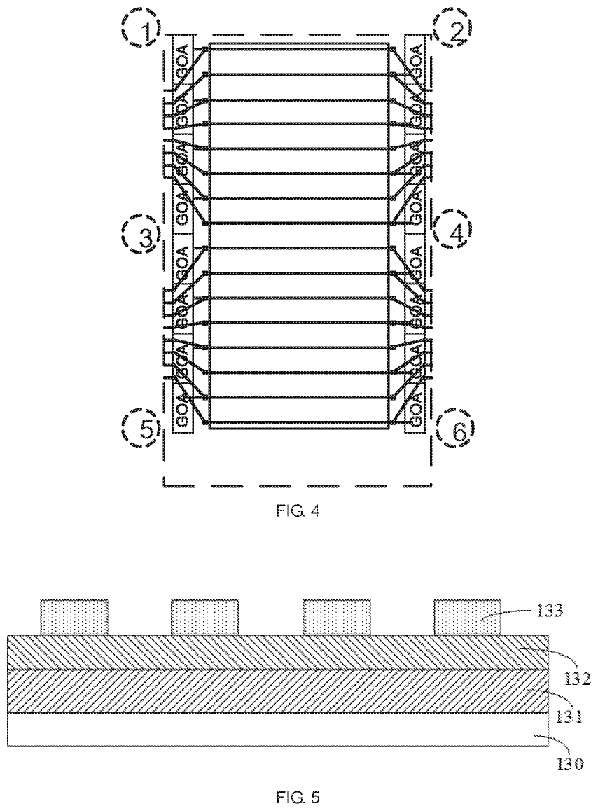

In order to achieve a better improvement of the effect for damages occurred at the electrostatic discharge monitoring points when the ESD of the process occurs, the connection points may bypass the electrostatic discharge monitoring points as the embodiment. Further refer to FIG. 4, FIG. 4 is a structural schematic top view of the display substrate in FIG. 3 after cutting. As can be seen in FIG. 4, points 1, 2, 3, 4, 5 and 6 are electrostatic discharge monitoring points, the connection points of the signal lines 13 bypass the electrostatic discharge monitoring points according to the trace manner of the signal lines 13, so as to further prevent damages and improve the yield of the product.

Preferably, all the signal lines 13 of all the panel areas 12 on the substrate 11 are electrically connected and all the signal lines 13 are connected together and grounded at the periphery of the substrate 11. Specifically, the signal lines 13 of the adjacent panel areas 12 are connected in the transverse direction of the substrate 11, marginal panel areas 12 are connected at the edges of the substrate 11, and they are connected together and grounded.

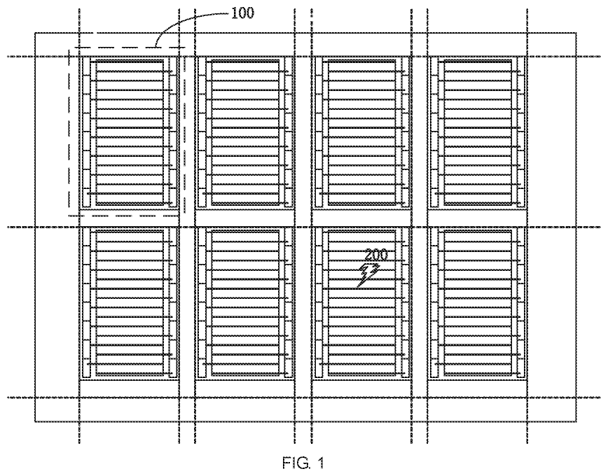

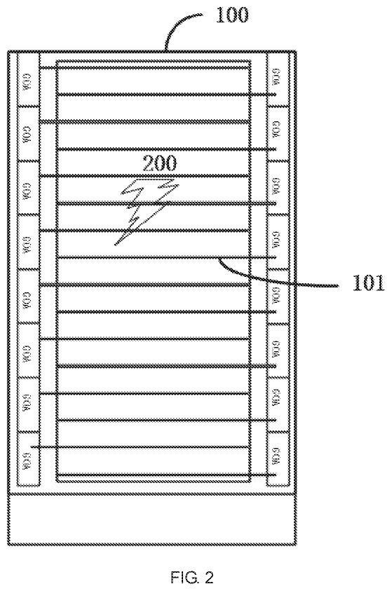

According to the embodiment, when the ESD of the process shown in FIG. 1 is generated at one point, the signal lines 13 of all the panel areas 12 cooperate with each other to resist the ESD of the process, so as to effectively improve the yield. And the conductive structure between the panel areas 12 bypasses the electrostatic discharge monitoring points, so that the design solution does not affect the normal performance of the panel and may further improve the yield of the process.

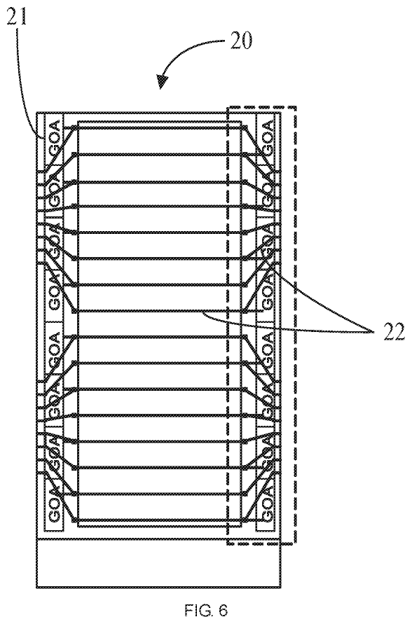

As shown in FIG. 6, FIG. 6 is a structural schematic top view of a display substrate according to another embodiment of the disclosure. In the embodiment, the display panel 20 includes a substrate 21 and signal lines 22 arranged on the substrate 21.

Wherein the signal lines 22 themselves extend to the edge of the substrate 21 for connecting to the signal lines 22 of another display panel 20 when the display panel 20 is manufactured, so as to cooperate with each other to resist the electrostatic damage. In other embodiments, the signal lines 22 themselves do not extend, and may extend to the edge of the substrate 21 through wires, so as to achieve the same effect.

When the signal lines 22 themselves extend to the edge of the substrate 21 by themselves or through wires, they uses a convergent extension manner, so that the connected signal lines 22 or the wires may bypass the electrostatic discharge monitoring points. That is, most of the signal lines 22 themselves are fold line structures or an obtuse angle greater than 90 degree and less than 180 degree is formed between the wires and the signal lines 22. A small part of the signal lines 22 may be linear structures and a small part of the wires and the signal lines 22 are located on the same straight line. The electrostatic discharge monitoring points are generally located at the corners of the substrate 21 and at the center of the longer side, so that the signal lines 22 themselves or the wires convergently extend in four sections when using the convergent extension manner.

The display panel 20 may be arranged to resist the ESD of the process during the glass panel process, and the signal lines 22 between the display panels 20 connected to each other by themselves or by the extended wire, such that the display panels 20 may cooperate with each other to resist to the ESD of the process, thereby effectively improving the occurrence of the damage at the electrostatic discharge monitoring points when the ESD of the process occurs and improving the yield of the product.

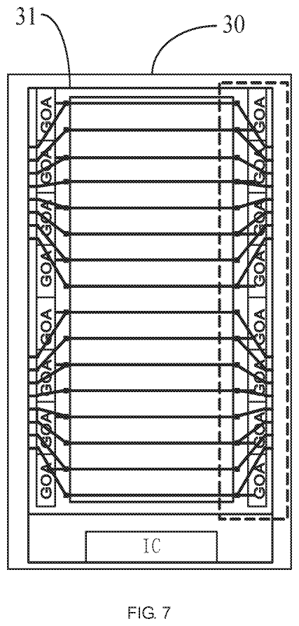

As shown in FIG. 7, FIG. 7 a structural schematic view of a display device according to an embodiment of the disclosure. The disclosure also discloses a display device 30, and the display device 30 includes the display panel 31 as described in the above embodiments.

Advantageous effects of the disclosure is that, different from the prior art, in the embodiment, at least part of the signal lines connected between the at least two panel areas are added on the display substrate, or the signal lines of the display substrate and another display substrate are connected. Therefore, through the connected signal lines, the different panel areas or display substrates may be conducted, may cooperate with each other to resist the electrostatic damage, thereby effectively improving the occurrence of the damage at the electrostatic discharge monitoring points when the ESD of the process occurs and improving the yield of the product.

The foregoing contents are only the detailed description of the embodiments of the disclosure which is not intended to limit the protection scope of the disclosure. Any equivalent structures or equivalent flow transformation made using the contents of the specification and the drawings of the disclosure or directly or indirectly applied to other related technical fields are similarly included in the protection scope of the disclosure.

What is claimed is:

1. A display substrate, comprising:
a substrate, defining a plurality of panel areas; and
signal lines, arranged in each of the panel areas;
wherein at least part of the signal lines between at least two of the panel areas are connected.

2. The display substrate according to claim 1, wherein
the signal lines are formed by using a first conductive layer and the display substrate further comprises a second conductive layer disposed on and insulated from the first conductive layer, at least part of the signal lines between at least two of the panel areas are connected through the second conductive layer.

3. The display substrate according to claim 2, wherein
the panel areas comprise a display area and a non-display area other than the display area, and connection points of the signal lines and the second conductive layer are located in the non-display area.

4. The display substrate according to claim 3, wherein
the connection points bypass electrostatic discharge monitoring points.

5. The display substrate according to claim 4, wherein
a plurality of adjacent signal lines of one panel area are connected to connection lines formed by the second conductive layer via holes in the non-display area, and the connection line corresponding to the adjacent signal lines continues to convergently extend to another panel area, so as to bypass the electrostatic discharge monitoring points and to connect to the corresponding signal lines of another panel area.

6. The display substrate according to claim 1, wherein
the signal lines are gate lines.

7. The display substrate according to claim 1, wherein
all the signal lines of all the panel areas on the substrate are electrically connected and all the signal lines are connected together and grounded at the periphery of the substrate.

8. The display substrate according to claim 2, wherein
the second conductive layer is formed of an ITO layer or a M3 layer.

9. A display panel, comprising:
a substrate; and
signal lines, disposed on the substrate;
wherein the signal lines extend to the edge of the substrate by itself or through wires for connecting to signal lines of another display substrate when the display panel is manufactured to cooperate with each other to resist electrostatic damages.

10. The display panel according to claim 9, wherein
the signal lines are gate lines.

11. The display panel according to claim 9, wherein
the signal lines are formed by using a first conductive layer and the display substrate further comprises a second conductive layer disposed on and insulated from the first conductive layer, and when the display panel is manufactured, at least part of the signal lines themselves or the wires between the two panel areas are connected through the second conductive layer.

12. The display panel according to claim 11, wherein
the second conductive layer is formed of an ITO layer or a M3 layer.

13. The display panel according to claim 11, wherein
the panel areas comprise a display area and a non-display area other than the display area, and connection points of the signal lines and the second conductive layer are located in the non-display area.

14. The display panel according to claim 11, wherein
the connection points bypass electrostatic discharge monitoring points.

15. A display device, wherein the display device comprises a display panel, and the display panel comprises:
a substrate;
signal lines, disposed on the substrate;
wherein the signal lines extend to the edge of the substrate by itself or through wires for connecting to signal lines of another display substrate when the display panel is manufactured to cooperate with each other to resist electrostatic damages.

16. The display device according to claim 15, wherein
the signal lines are gate lines.

17. The display panel according to claim 15, wherein
the signal lines are formed by using a first conductive layer and the display substrate further comprises a second conductive layer disposed on and insulated from the first conductive layer, and when the display panel is manufactured, at least part of the signal lines themselves or the wires between the two panel areas are connected through the second conductive layer.

18. The display panel according to claim 17, wherein
the second conductive layer is formed of an ITO layer or a M3 layer.

19. The display panel according to claim 18, wherein
the panel areas comprise a display area and a non-display area other than the display area, and the connection points of the signal lines and the second conductive layer are located in the non-display area.

20. The display panel according to claim 18, wherein
the connection points bypass electrostatic discharge monitoring points.
